(19) United States
(12) Patent Application Publication
(10) Pub. No.: US 2006/0203446 A1
(43) Pub. Date: Sep. 14, 2006

(54) Fan for use in an electronic system

(75) Inventors: Jagadeesh Radhakrishnan, Folsom, CA (US); Wen Wei, Beaverton, OR (US)

Correspondence Address: Grossman, Tucker, Perreault & Pfleger, PLLC, PortfolioIP, P.O. Box 52050, Minneapolis, MN, 55402, US

(73) Assignee: Intel Corporation

(21) Appl. No.: 11/074,535

(22) Filed: Mar. 8, 2005

(51) Int. Cl. H05K 7/20; F28F 7/00

(52) U.S. Cl. 361/695; 165/80.3

(57) ABSTRACT

A fan may include a fan housing and an integrated electrical connector extending from the fan housing for engaging a mating connector. The fan may also include one or more retractable handles extending from the fan housing on a side opposite the integrated electrical connector. The fan may further include one or more guides on the housing for engaging a fan tray and guiding the fan when the fan is inserted and removed. Of course, many alternatives, variations, and modification are possible without departing from this embodiment.

### FIELD

The present disclosure relates to fans for use in a chassis of an electronic system.

### BACKGROUND

Increases in processor speeds and circuit board densities have resulted in an increase in the heat generated by computer systems and other electronics systems. In an advanced telecommunications computing architecture (ATCA) system, for example, dense blades (i.e., circuit boards) populated with silicon chips, such as single board computer (SBC) blades with microprocessors, may dissipate up to 200 W of power per blade, which may result in a total dissipation of 2800 W in a 14 slot chassis. The heat generated by such power dissipation rate may cause semiconductor performance degradation, mean time between failure (MTBF) reduction and even catastrophic damage. Thus, the performance and reliability of computer and other electronic systems may be dependent on the ability to provide adequate cooling in the chassis.

In computer or electronics systems, such as ATCA systems, heat generated by various components of the system may be removed using forced convection. In a forced convection cooling system, a fan may be used to circulate air within a housing or chassis of the computer or electronics system. In many systems, the fan may be used to force the intake of air from the exterior of the computer or electronics system, pass the air through the housing or chassis, and exhaust heated air from the housing or chassis.

The fans may be mechanically secured within the housing or chassis and electrically connected to components of the system. Some existing fan designs include electrical connectors that are electrically and mechanically connected to the fan via electrical cables (i.e., the connector hangs from the end of a cable connected to the fan). This design may present problems when plugging and unplugging the fans because the electrical connector is plugged in separately from the insertion of the fan. The cables may also interfere with other components in the electronic system. In ATCA applications, for example, the cables may obstruct the plugging and unplugging of blades during normal operations and may pose reliability and serviceability concerns by accidentally unplugging or cutting the power supply to the fans.

### BRIEF DESCRIPTION OF THE DRAWINGS

Features and advantages of the claimed subject matter will be apparent from the following detailed description of embodiments consistent therewith, which description should be considered with reference to the accompanying drawings, in which:

FIG. 1 is a schematic illustration of an embodiment of a system including a fan consistent with the present disclosure;

FIG. 2 is a perspective view of one embodiment of a fan tray receiving a fan, consistent with the present disclosure;

FIG. 3 is a perspective view of the fan shown in FIGS. 1 and 2;

FIG. 4 is a perspective view of the fan housing of the fan shown in FIG. 3;

FIG. 5 is a partial side view of one embodiment of an integrated electrical connector on a fan housing engaging a mating connector;

FIG. 6 is a top schematic view of one embodiment of a guide on a fan housing engaging a mating guide;

FIG. 7 is a side schematic view of one embodiment of a retention keying structure on a fan housing engaging a mating structure; and

FIG. 8 is a schematic illustration of a telecom cabinet and one or more chassis, consistent with the present disclosure.

Although the following detailed description will proceed with reference being made to particular illustrated embodiments, it should be understood that numerous variations and modifications will be apparent to those having skill in the art. Accordingly, the claimed subject matter should be interpreted broadly without limitation to the particular illustrated embodiments herein.

### DETAILED DESCRIPTION

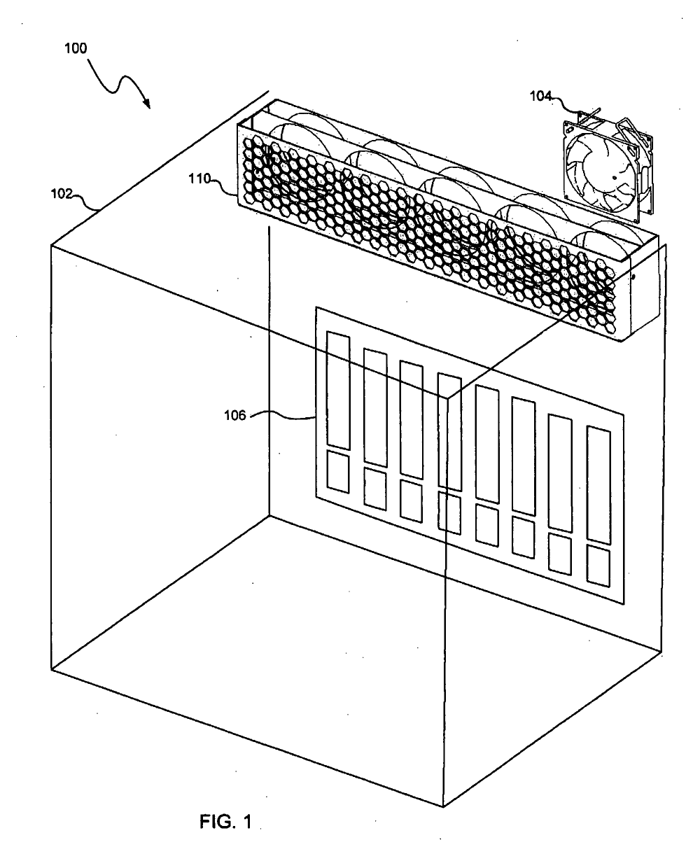

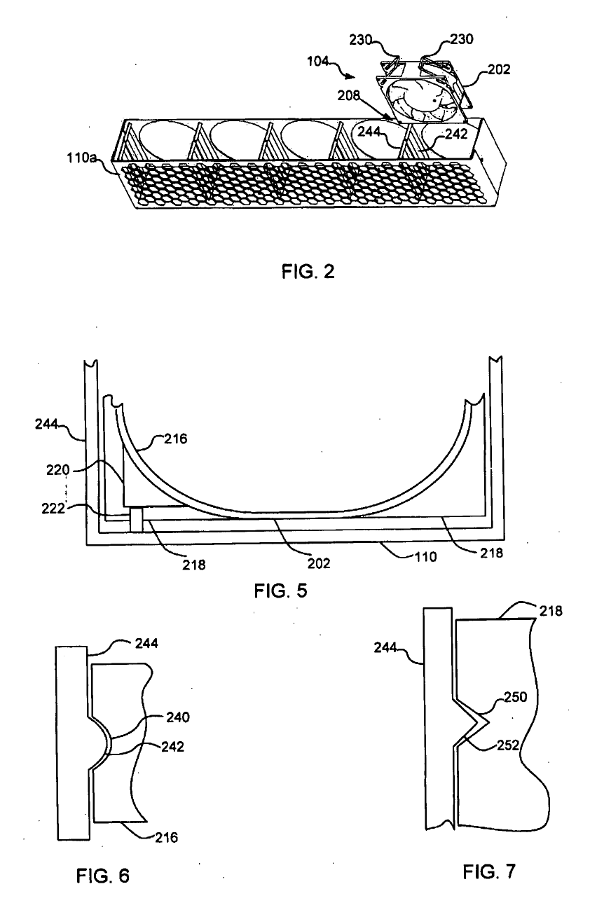

Referring to FIG. 1, an embodiment of a computer or electronic system 100 may generally include a chassis 102 to house electronic components and at least one fan 104 to provide forced convection through the chassis 102. As disclosed in greater detail below, the fan 104 may be hot swappable and capable of being inserted and removed without having to separately engage and disengage a power cable. In one embodiment, one or more fans 104 may be inserted in and removed from a fan tray 110 located in the chassis 102. The fan tray 110 may be used to support and position the fan(s) 104 within the chassis 102. Another embodiment of a fan tray 110a for receiving and supporting one or more fans 104 is shown in FIG. 2. The fan(s) 104 may also be directly inserted in and removed from other supporting structures in the chassis 102.

According to one embodiment, the chassis 102 may be an advanced telecommunications computing architecture (advanced TCA or ATCA) chassis or shelf, complying with, or compatible with, PCI Industrial Computer Manufacturers Group (PICMG), Advanced Telecommunications Computing Architecture (ATCA) Base Specification, PIGMG 3.0 Revision 1.0, published Dec. 30, 2002. According to such an embodiment, the chassis 102 may include a backplane 106 to connect to one or more circuit board assemblies, such as ATCA boards or blades. The fan 104 may be used in any electronic system in which forced convection cooling is used including, but not limited to, high density and small form factor ATCA systems. Although the exemplary embodiment refers to use in bladed systems, the fan 104 may also be used in other form factors such as rack-mount systems.

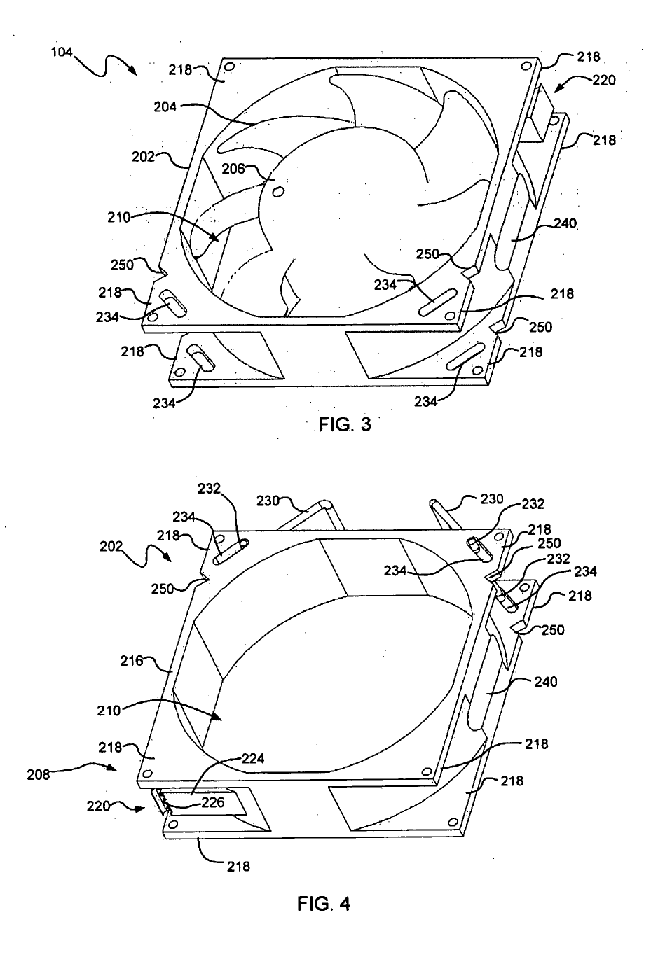

Referring to FIGS. 3 and 4, one embodiment of the fan 104 is shown in greater detail. The fan 104 may include a fan housing 202 and a fan blade 204 rotatably mounted within the fan housing 202. The fan blade 204 may be centrally mounted within the fan housing 202 with a rotating mechanism 206 (e.g., rotor, bearings, etc.) known to those skilled in the art. The fan blade 204 may have various blade designs known to those skilled in the art.

According to one embodiment, the fan housing 202 defines an air passage region 210 and the blade 204 rotates within the air passage region 210 to draw air through the air passage region 210. The fan housing 202 may include a frame 216 having sides defining the air passage region 210 and one or more flanges 218 extending from corners of the frame 216. The fan housing 202 may be made of molding injected plastics or other materials known to those skilled in the art. Although the illustrated embodiment shows a generally square shaped fan housing 202 including flanges 218, those skilled in the art will recognize that the fan housing 202 may have other shapes and configurations.

The fan 104 may also include at least one integrated electrical connector 220 extending from the fan housing 202 and configured to engage directly with a mating electrical connector 222, as shown in FIG. 5. The integrated electrical connector 220 may include a housing 224 defining sockets 226 holding contacts (not shown) configured to engage mating contacts on the mating electrical connector 222. As used herein, “integrated” means that the housing 224 of the electrical connector 220 extends directly from the fan housing 202, instead of being mechanically connected to the fan housing 202 via electrical cables. The integrated electrical connector 220 may be integrated by forming the connector housing 224 as one piece with the fan housing 202 or by mounting or attaching the connector housing 224 to the fan housing 202. Integrating the electrical connector 220 enables a hot swappable fan design in that the electrical connector 220 may be engaged or “plugged in” with the insertion of the fan 104 into the chassis 102.

In one embodiment, the integrated electrical connector 220 may provide three (3) connections—power, ground and fan speed. The integrated electrical connector 220 may be electrically connected to the rotating mechanism of the fan 104 using cables extending from the integrated electrical connector 220 to the rotating mechanism 206. The electrical connection between the integrated electrical connector 220 and the rotating mechanism 206 may also be routed internally, for example, by conductive paths along the fan housing 202. The integrated electrical connector 220 may have any design (i.e., shape, contacts, etc.) known to those skilled in the art.

In one embodiment, the integrated electrical connector 220 may extend from the bottom corner 208 of the fan housing 202 to facilitate engagement of the connector 220 with the mating electrical connector 222 when inserting the fan 104 into the chassis 102. The integrated electrical connector 220 may extend from the frame 216 of the fan housing 202 and between two of the flanges 218. Alternatively, the integrated electrical connector 220 may also extend from other locations on the fan housing 202. The mating electrical connector 222 may extend from the fan tray 110, 110a or from another supporting structure in the chassis 102 and may be electrically connected to a chassis power supply.

One embodiment of the fan 104 may also include one or more retractable handles 230 extending from the fan housing 202 and movable between a handling position and a retracted position. In one embodiment, the retractable handle(s) 230 may be located on a side of the fan housing 202 generally opposite the integrated electrical connector 220. Thus, a user may pull on the retractable handle(s) 230 to apply a disengaging force to the integrated electrical connector 220 when removing the fan 104.

In one embodiment, the handles 230 may be pivotably coupled to one or more of the flanges 218 such that the handles 230 are capable of being positioned between the flanges 218 in the retracted position. The handles 230 may include ends 232 that engage slots 234 in the flanges 218, which enable the handles 230 to pivot and slide to the retracted position. Although the handles 230 are shown with a generally U-shaped construction, other shapes and configurations may be used. The retractable handle(s) 230 advantageously facilitate access to and removal of the fan 104, thereby facilitating serviceability, for example, if the fan fails and must be replaced. Allowing the handles 230 to retract saves headroom above the fan, which is particularly advantageous in a space-constrained ATCA platform.

One embodiment of the fan housing 202 may also include one or more guides 240 shaped and configured to engage mating guide structures 242, as shown in FIG. 6. The guides 240 may be formed in the frame 216 of the fan housing 202 on one or more sides of the fan housing 202. The mating guide structures 242 may be located on walls 244 in the fan tray 110a (see FIG. 2) or in some other supporting structure in the chassis 102. Thus, the guides 240 may guide the fan 104 as it is inserted or removed and may facilitate alignment of the integrated electrical connector 220 as it engages the mating electrical connector 222. In the illustrated embodiment, the guides 240 are formed as concave channels in the frame 216, although those skilled in the art will recognize that the guides may have other shapes and configurations.

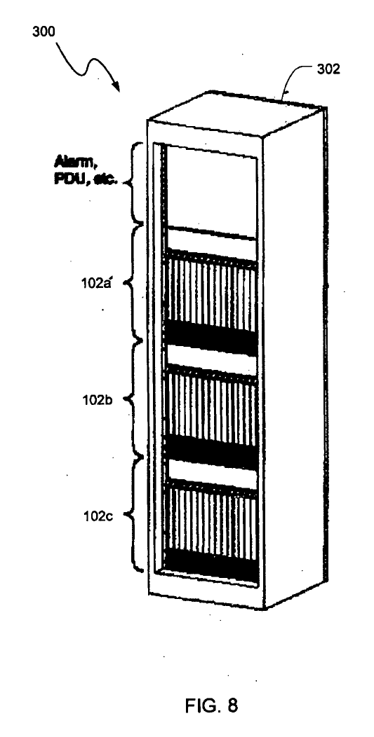

The fan housing 202 may further include one or more retention keying structures 250 configured to engage mating retention keying structures 252, as shown in FIG. 7. The retention keying structures 250 may be formed in one or more of the flanges 218 on the sides of the housing 202. The mating retention keying structures 252 may be located on walls 244 in the fan tray 110a or in some other supporting structure in the chassis 102. The retention keying structures 250 may be used to hold the fan housing 202 in place during operation of the fan 104. In the illustrated embodiment, the retention keying structures 250 are V-shaped notches, although those skilled in the art will recognize that the retention keying structures 250 may have other shapes and configurations.

In use, the guides 240 on fan 104 may be aligned and engaged with the corresponding structures in the chassis 102 or fan tray 110, 110a. The fan 104 may then be pushed to both insert the fan 104 and to engage the integrated electrical connector 220. The fan 104 may be pushed until the retention keying structures 250 engage the corresponding structures in the chassis 102 or fan tray 110, 110a. To remove the fan 104, the handle(s) 230 may be moved from the retracted position to the handling position. The handle(s) 230 may then be pulled to disengage the integrated electrical connector 220 from the mating electrical connector 222 and to remove the fan 104 from the chassis 102 or fan tray 110.

Referring to FIG. 8, a system 300 such as a telecom cabinet may include one or more chassis 102a, 102b, 102c within a cabinet 302. One or more of the chassis 102a, 102b, 102c may include at least one fan with a fan housing, consistent with any embodiment described herein. The cabinet 302 may include, for example, a power supply or a power entry module (PEM) to each of the individual chassis 102a, 102b, 102c disposed in the cabinet 302. Additionally, as mentioned above, the frame may electrically couple one or more of the chassis 102a, 102b, 102c to at least one other chassis or shelf.

According to an alternative embodiment, rather than being disposed in a common frame, a system consistent with the present disclosure may include a plurality of chassis or shelves that may be individually hardwired to one another. One or more of the plurality of chassis or shelves may include at least one fan with a fan housing, consistent with any embodiment described herein. Additionally, each of the plurality of chassis or shelves may be powered by an individual power supply and/or may be separately powered by a common power supply. Such a system may, therefore, provide a greater freedom in the physical arrangement and interrelation of the plurality of chassis or shelves.

Thus, one embodiment of a fan may include a fan housing defining an air passage region. An integrated electrical connector may extend from the fan housing to engage a mating electrical connector. A fan blade may be rotatably mounted within the air passage region of the fan housing such that the fan blade is capable of moving air through the air passage region of the fan housing.

Consistent with another embodiment, a system may include a frame comprising at least one chassis and at least one fan in the frame. The fan may include a fan housing defining an air passage region and an integrated electrical connector extending from the fan housing and configured to engage a mating electrical connector. A fan blade may be rotatably mounted within the air passage region of the fan housing such that the fan blade is capable of moving air through the air passage region of the fan housing.

Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Other modifications, variations, and alternatives are also possible. Accordingly, the claims are intended to cover all such equivalents.

What is claimed is:

1. A fan comprising:
a fan housing defining an air passage region;
an integrated electrical connector extending from said fan housing and configured to engage a mating electrical connector; and
a fan blade rotatably mounted within said air passage region of said fan housing such that said fan blade is capable of moving air through said air passage region of said fan housing.

2. The fan of claim 1 wherein said integrated electrical connector extends from a bottom corner of said fan housing.

3. The fan of claim 1 wherein said fan housing further comprises a frame and flanges extending from said frame at corners of said fan housing, and wherein said integrated electrical connector extends from said frame between two of said flanges.

4. The fan of claim 1 further comprising at least one retractable handle coupled to said fan housing, said retractable handle being configured to move between a handling position and a retracted position.

5. The fan of claim 4 wherein said fan housing further comprises flanges extending from at least one corner of said fan housing, and wherein said retractable handle is pivotably coupled to at least one of said flanges and is capable of being positioned between said flanges in said retracted position.

6. The fan of claim 5 wherein said retractable handle engages at least one slot in said at least one of said flanges such that said handle is capable of pivoting and sliding to said retracted position.

7. The fan of claim 4 wherein said integrated electrical connector is located on a first side of said fan housing, and wherein said at least one retractable handle is located on a second side of said fan housing opposite said first side.

8. The fan of claim 1 wherein said fan housing further comprises at least one guide located on at least one side of said fan housing, said guide being capable of guiding said fan housing into a chassis.

9. The fan of claim 1 wherein said housing further comprises at least one retention keying structure capable of engaging a mating retention keying structure in a chassis.

10. A system comprising:
a cabinet comprising at least one chassis; and
at least one fan in said frame, said fan comprising:
a fan housing defining an air passage region;
an integrated electrical connector extending from said fan housing and configured to engage a mating electrical connector in said chassis; and
a fan blade rotatably mounted within said air passage region of said fan housing such that said fan blade is capable of moving air through said air passage region of said fan housing.

11. The system of claim 10 wherein said integrated electrical connector of said fan is configured to plug directly into a mating electrical connector in said chassis without using a power cable therebetween.

12. The system of claim 10 wherein said fan further comprises at least one retractable handle coupled to said fan housing, said retractable handle being configured to move between a handling position and a retracted position.

13. The system of claim 10 wherein said fan housing further comprises at least one guide located on at least one side of said fan housing, said guide being capable of guiding said fan housing into said chassis.

14. The system of claim 10 wherein said housing further comprises at least one retention keying structure capable of engaging a mating retention keying structure in said chassis.

15. A fan housing comprising:
a frame defining an air passage region, said frame including at least one guide located on at least one side of said fan housing, said guide being capable of guiding said fan housing into a fan tray;
an integrated electrical connector extending from a first side of said frame and configured to engage a mating electrical connector in said fan tray; and
at least one retractable handle coupled to said frame on a second side opposite said first side, said at least one retractable handle being configured to move between a handling position and a retracted position.

16. The fan housing of claim 15 wherein said fan housing further comprises flanges extending from said frame at corners of said fan housing, and wherein said integrated electrical connector extends from said frame between two of said flanges.

17. The fan housing of claim 16 wherein said retractable handle engages at least one slot in said at least one of said flanges such that said handle is capable of pivoting and sliding to said retracted position.

18. The fan housing of claim 15 wherein said housing further comprises at least one retention keying structure capable of engaging a mating retention keying structure in said chassis.

19. A method of removing a fan from a chassis, said fan including a fan housing, an integrated electrical connector extending from said housing, and at least one retractable handle coupled to said housing, said method comprising:
moving said retractable handle on said fan housing from a retracted position to a handling position; and
pulling said retractable handle to disengage said integrated electrical connector on said fan housing from a mating electrical connector in said chassis and to remove said fan from said chassis.

20. A method of inserting a fan into a chassis, said fan including a fan housing, an integrated electrical connector extending from said housing, and guides on said fan housing, said method comprising:
engaging said guides on said fan housing with mating guides in said chassis; and
pushing said fan to insert said fan into said chassis and to engage said integrated electrical connector with a mating electrical connector in said chassis.
